(19) United States
(12) Patent Application Publication
(10) Pub. No.: US 2020/0071813 A1
(43) Pub. Date: Mar. 5, 2020

(54) MASK ASSEMBLY AND APPARATUS AND METHOD FOR MANUFACTURING DISPLAY APPARATUS

(71) Applicant: Samsung Display Co., Ltd., Yongin-Si (KR)

(72) Inventors: Jongbum Kim, Yongin-si (KR); Jaesuk Moon, Yongin-si (KR); Seungjin Lee, Yongin-si (KR)

(21) Appl. No.: 16/395,255

(22) Filed: Apr. 26, 2019

(30) Foreign Application Priority Data
Aug. 29, 2018 (KR) 10-2018-0102174

(51) Int. Cl. C23C 14/04; H01L 51/00; H01L 51/56; H01L 27/32

(52) U.S. Cl. CPC C23C 14/042; H01L 51/0011; H01L 2227/323; H01L 27/3244; H01L 51/56

(57) ABSTRACT

A mask assembly includes a mask frame including a first surface and a second surface facing each other; a support frame arranged on the first surface of the mask frame; a mask sheet arranged on the support frame and including at least one opening; and a deformation prevention frame arranged on the second surface of the mask frame.

### CROSS-REFERENCE TO RELATED APPLICATION

This application claims the benefit of Korean Patent Application No. 10-2018-0102174, filed on Aug. 29, 2018, in the Korean Intellectual Property Office, the disclosure of which is incorporated herein in its entirety by reference.

### BACKGROUND

### 1. Field

One or more embodiments of the present disclosure relate to an apparatus and method, and more particularly, to a mask assembly, an apparatus for manufacturing a display apparatus, and a method of manufacturing the display apparatus.

### 2. Description of the Related Art

Recently, portable electronic devices providing mobility to users such as tablet personal computers (PCs), and mobile phones have been recently widely used.

A portable electronic device typically includes a display device that is capable of providing a user with visual information such as images or videos. Sizes of driving components of the display device have been reduced as the size of the display device itself is reduced. Recently, a display device that is capable of being folded or bent has been developed.

A mask assembly may be used to form layers of a display device, and the precise assembly and alignment of the mask assembly according to the designed specification may be critical in determining the sharpness of an image to be displayed by the display device being manufactured.

### SUMMARY

According to a related art, a mask assembly may exhibit a parameter that is different from a design parameter due to a tensile force applied during manufacturing of the mask assembly or thermal deformation caused when a display apparatus having a freeform display area is manufactured by using the mask assembly. One or more embodiments of the present disclosure relate to a mask assembly having reduced deformation, an apparatus for manufacturing a display apparatus, a method of manufacturing the display apparatus, and the display apparatus.

Additional aspects will be set forth in part in the following description and, in part, will be apparent from the description, or may be learned by practice of the presented embodiments.

According to one or more embodiments, a mask assembly includes: a mask frame including a first surface and a second surface facing each other; a support frame on the first surface of the mask frame; a mask sheet on the support frame including at least one opening; and a deformation prevention frame on the second surface of the mask frame.

The support frame and the deformation prevention frame may face each other with respect to the mask frame.

The support frame and the deformation prevention frame may be coupled to the mask frame in a state in which a tensile force is applied to the support frame and the deformation prevention frame.

A width of the support frame in a direction perpendicular to a lengthwise direction of the support frame may be greater than a width of the deformation prevention frame in a direction perpendicular to a lengthwise direction of the deformation prevention frame.

The deformation prevention frame may be arranged perpendicular to a lengthwise direction of the mask sheet.

The mask assembly may include a plurality of deformation prevention frames, and at least two of the plurality of deformation prevention frames may be on the mask frame to intersect with each other.

The support frame and the deformation prevention frame may have different shapes from each other.

According to one or more embodiments, an apparatus for manufacturing a display apparatus, the apparatus includes: a chamber in which a display substrate is; a mask assembly facing the display substrate in the chamber; and a source portion facing the mask assembly in the chamber, wherein the mask assembly includes: a mask frame including a first surface and a second surface facing each other; a support frame on the first surface of the mask frame; a mask sheet on the support frame including at least one opening; and a deformation prevention frame on the second surface of the mask frame.

The support frame and the deformation prevention frame may face each other with respect to the mask frame.

The support frame and the deformation prevention frame may be coupled to the mask frame in a state in which a tensile force is applied to the support frame and the deformation prevention frame.

A width of the support frame in a direction perpendicular to a lengthwise direction of the support frame may be greater than a width of the deformation prevention frame in a direction perpendicular to a lengthwise direction of the deformation prevention frame.

The deformation prevention frame may be arranged perpendicular to a lengthwise direction of the mask sheet.

The mask assembly may include a plurality of deformation prevention frames, and at least two of the plurality of deformation prevention frames may be on the mask frame to intersect with each other.

The support frame and the deformation prevention frame may have different shapes from each other.

According to one or more embodiments, a method of manufacturing a display apparatus, the method includes: arranging a display substrate and a mask assembly in a chamber; aligning the display substrate and the mask assembly with each other; and supplying a deposition material from a source portion to the mask assembly, and depositing the deposition material on the display substrate through the mask assembly, wherein the mask assembly includes: a mask frame including a first surface and a second surface facing each other; a support frame on the first surface of the mask frame; a mask sheet on the support frame including at least one opening; and a deformation prevention frame on the second surface of the mask frame.

The support frame and the deformation prevention frame may face each other with respect to the mask frame.

The support frame and the deformation prevention frame may be coupled to the mask frame in a state in which a tensile force is applied to the support frame and the deformation prevention frame.

A width of the support frame in a direction perpendicular to a lengthwise direction of the support frame may be greater than a width of the deformation prevention frame in a direction perpendicular to a lengthwise direction of the deformation prevention frame.

The deformation prevention frame may be arranged perpendicular to a lengthwise direction of the mask sheet.

The mask assembly may include a plurality of deformation prevention frames, and at least two of the plurality of deformation prevention frames may be on the mask frame to intersect with each other.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of an apparatus for manufacturing a display apparatus, according to an embodiment;

FIG. 2 is an exploded perspective view of a mask assembly of FIG. 1;

FIG. 3 is a plan view of a display apparatus manufactured by using the apparatus for manufacturing the display apparatus of FIG. 1;

FIG. 4 is a cross-sectional view taken along line A-A of FIG. 3;

FIG. 5 is an exploded perspective view of a mask assembly according to an embodiment; and

FIG. 6 is a cross-sectional view of a display apparatus manufactured by using the mask assembly of FIG. 5.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the drawings, to explain aspects of the present disclosure. As used herein, the term “and/or” includes any and all combinations of one or more of the associated listed items. Expressions such as “at least one of,” when preceding a list of elements, may modify the entire list of elements and may not modify the individual elements of the list.

As the present disclosure allows for various changes and numerous embodiments, exemplary embodiments will be illustrated in the drawings and described in detail in the written description. The attached drawings for illustrating one or more embodiments are referred to gain a sufficient understanding, the merits thereof, and the objectives accomplished by the implementation. However, the embodiments may have different forms and should not be construed as being limited to the descriptions set forth herein.

The exemplary embodiments will be described below in more detail with reference to the accompanying drawings. Those components that are the same or are in correspondence are rendered the same reference numeral regardless of the figure number, and redundant explanations are omitted.

While such terms as “first,” “second,” etc., may be used to describe various components, such components must not be limited to the above terms. The above terms are used only to distinguish one component from another.

An expression used in a singular form encompasses the expression of a plural form, unless it has a clearly different meaning in the context.

In the present disclosure, it is to be understood that the terms “including,” “having,” and “comprising” are intended to indicate an existence of the features, numbers, steps, actions, components, parts, or combinations thereof disclosed in the present disclosure, and are not intended to preclude a possibility that one or more other features, numbers, steps, actions, components, parts, or combinations thereof may exist or may be added.

It will be understood that when a layer, region, or component is referred to as being “formed on” another layer, region, or component, it can be directly or indirectly formed on the other layer, region, or component. That is, for example, one or more intervening layers, regions, or components may be present.

Sizes of components illustrated in the drawings may be exaggerated for convenience of explanation. In other words, sizes and thicknesses of components in the drawings are arbitrarily illustrated for convenience of explanation, and the following embodiments are not limited thereto.

When a certain embodiment may be implemented differently, a specific process order may be performed differently from a described order. For example, two consecutively described processes may be performed substantially at the same time or performed in an order opposite to the described order.

In the embodiments below, when layers, areas, elements, or the like are referred to as being “connected,” it will be understood that they can be directly connected or one or more intervening layers, areas, or elements may be present therebetween. For example, when layers, areas, elements, or the like are referred to as being “electrically connected,” they can be directly electrically connected or indirectly electrically connected, and one or more intervening layers, areas, or elements may be present therebetween.

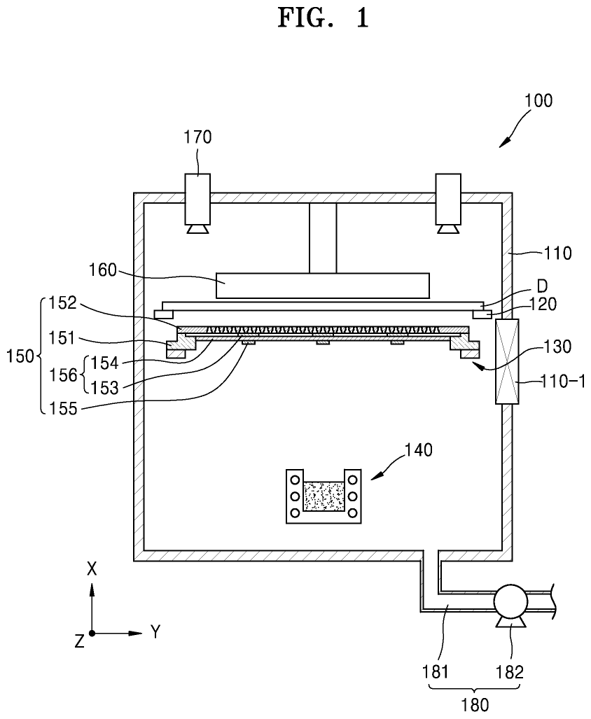

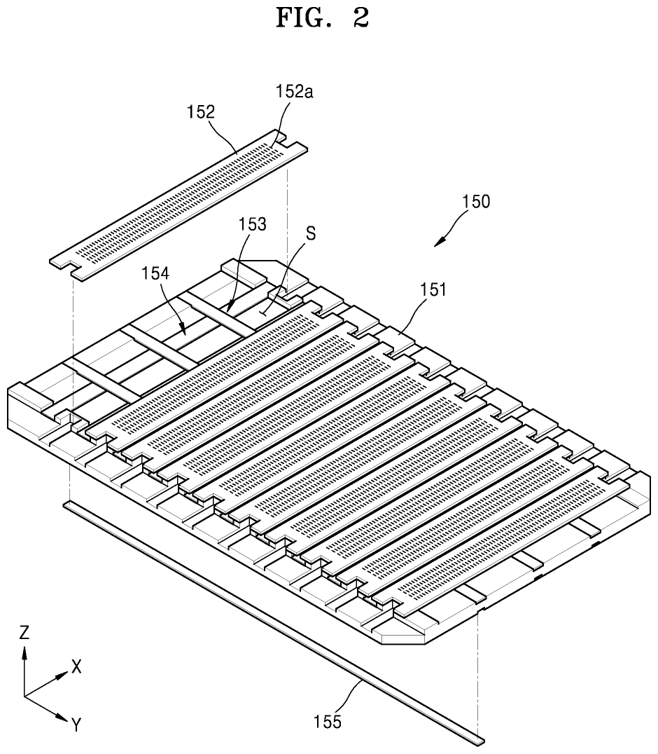

FIG. 1 is a cross-sectional view of an apparatus 100 for manufacturing a display apparatus, according to an embodiment. FIG. 2 is an exploded perspective view of a mask assembly 150 of FIG. 1.

Referring to FIGS. 1 and 2, the apparatus 100 for manufacturing a display apparatus may include a chamber 110, a first supporter 120, a second supporter 130, a mask assembly 150, a source portion 140, a magnetic force portion 160, a vision portion 170, and a pressure adjuster 180.

The chamber 110 may include a space therein and may have an opening part. A gate valve 110-1 may be provided at the opening part of the chamber 110. In this case, the opening part of the chamber 110 may open or close according to an operation of the gate valve 110-1.

The first supporter 120 may support a display substrate D mounted thereon. The first supporter 120 may be of a plate type that is fixed in the chamber 110. In another embodiment, the first supporter 120, on which the display substrate D is mounted, may be of a shuttle type that is linearly movable in the chamber 110. In yet another embodiment, the first supporter 120 may include an electrostatic chuck or an adhesive chuck that is fixed in the chamber 110 or arranged to be movable up/down. Hereinafter, for convenience of description, an example in which the first supporter 120 is of a plate type that is fixed in the chamber 110 will be described in detail. However, it is noted that the first supporter 120 may be of other types, fixed in the chamber 110 or movable, without deviating from the scope of the present disclosure.

The mask assembly 150 may be mounted on the second supporter 130. The second supporter 130 may be arranged inside the chamber 110. The second supporter 130 may finely adjust a position of the mask assembly 150 with respect to other portions such as the first supporter 120, the source portion 140, the magnetic force portion 160, etc. inside the chamber 110. The second supporter 130 may include an additional driver or an alignment device to move the mask assembly 150 in different directions.

The source portion 140 may be arranged facing the mask assembly 150. The source portion 140 may accommodate a deposition material and may vaporize or sublimate the deposition material by applying heat to the deposition material. The source portion 140 may be fixed in the chamber 110 or may be arranged inside the chamber 110 to be linearly movable in one or more directions. Hereinafter, for convenience of description, an example in which the source portion 140 is fixed in the chamber 110 will be described in detail. However, it is noted that the source portion 140 may be movable inside the chamber 110 without deviating from the scope of the present disclosure.

The mask assembly 150 may include a mask frame 151, a mask sheet 152, one or more support frames 156, and one or more deformation prevention frames 155.

The mask assembly 150 may further include a plurality of frames connected to one another to form a space therein. In an embodiment, the mask assembly 150 may be of a frame type having one opening at a center portion thereof. In another embodiment, the mask assembly 150 may be of a grating type such as a window frame including a plurality of openings. Hereinafter, for convenience of description, an example in which the mask assembly 150 includes one opening at the center portion thereof will be described in detail.

At least one mask sheet 152 may be provided, and when two or more mask sheets 152 are provided, the two or more mask sheets 152 may be provided as being spaced apart from each other on the mask frame 151. In this case, the two or more mask sheets 152 may be arranged in a first direction (e.g., one of a Y-axis direction and an X-axis direction in FIG. 1).

The mask sheet 152 may include at least one opening 152a. In particular, the mask sheet 152 may include a plurality of openings 152a in a lengthwise direction thereof. The plurality of openings 152a may be arranged with constant intervals therebetween and may be provided in a front surface of the mask sheet 152.

According to one embodiment, a plurality of support frames 156 may be arranged between the mask frame 151 and the mask sheet 152. The support frames 156 may define a boundary of a deposition area S through which the deposition material to be vapor-deposited on the display substrate D passes. The plurality of support frames 156 may be arranged as being spaced from one another on the mask frame 151. For example, the plurality of support frames 156 may be arranged as being spaced apart from one another in a lengthwise direction of the mask sheet 152. In addition, each of the support frames 156 may be arranged at a predetermined angle with respect to the mask sheet 152. In this case, each of the support frames 156 may be arranged in a direction perpendicular to the lengthwise direction of the mask sheet 152 (e.g., X-axis direction or Y-axis direction in FIG. 1). In another embodiment, the support frames 156 may be arranged in the lengthwise direction of the mask sheet 152. In yet another embodiment, among the plurality of support frames 156, some of the plurality of support frames 156 may be arranged in the lengthwise direction of the mask sheet 152, and others of the plurality of support frames 156 may be arranged to make a predetermined angle with respect to the lengthwise direction of the mask sheet 152. In this case, at least two of the plurality of support frames 156 may be arranged to intersect with each other in a plan view. As illustrated in FIG. 2, the plurality of support frames 156 may include a plurality of first support frames 153 and a plurality of second support frames 154. The plurality of first support frames 153 may be arranged across a plurality of mask sheets 152 to make a predetermined angle with respect to the lengthwise direction of the plurality of mask sheets 152, and the plurality of second support frames 154 may be arranged in the lengthwise direction of the plurality of mask sheets 152. Each of the plurality of second support frame 154 may be arranged between two adjacent mask sheets 152.

According to one embodiment, a plurality of deformation prevention frames 155 may be arranged on the mask frame 151 to correspond to the support frames 156. In one embodiment, the plurality of deformation prevention frame 155 may be arranged on an opposite side of the mask frame 151 facing the plurality of first support frames 153. In this case, a width of the deformation prevention frames 155 may be less than those of the support frames 156, and the width of the first support frames 153 and the second support frames 154 of the support frames 156 may be the same. The width of the deformation prevention frames 155 and the widths of the support frames 156 may be measured in a direction perpendicular to their lengthwise direction. Because the width of the deformation prevention frames 155 is less than those of the support frames 156, the deposition material that is vapor-deposited on the display substrate D may not be blocked by the deformation prevention frames 155. According to one embodiment, the plurality of deformation prevention frames 155 may be arranged to correspond at least some of the plurality of support frames 156. For example, the plurality of deformation prevention frames 155 may include a plurality of first deformation prevention frames corresponding to the plurality of first support frames 153, and a plurality of second deformation prevention frames corresponding to the plurality of second support frames 154. In this case, the first deformation prevention frames and the second deformation prevention frames may be arranged to intersect with each other, similar to the first support frames 153 and the second support frames 154.

In addition, according to a method of manufacturing the mask assembly 150, the support frames 156 may be arranged on the mask frame 151 and fixed to the mask frame 151. In one embodiment, the support frames 156 may be fixed to the mask frame 151 as being pulled (e.g., applying a tensile force to the support frames 156 to elongate it in a lengthwise direction from its original length), and an end of each of the support frames 156 may be inserted into a groove (not shown) formed in the mask frame 151 to prevent interference with the mask sheet 152.

In the above case, since the support frames 156 are fixed to the mask frame 151 by being pulled, the mask frame 151 may be curved or deformed. In this case, when the mask sheet 152 is attached to the mask frame 151, a gap may occur between the mask sheet 152 and the mask frame 151, or the mask sheet 152 may be curved due to the curving or deformation of the mask frame 151.

To address the above issue, the deformation prevention frame 155 may be arranged on a surface of the mask frame 151 that is different from a surface of the mask frame 151 to which the support frames 156 are fixed. The deformation prevention frame 155 may be also pulled and fixed to the mask frame 151. In this case, opposite ends of the deformation prevention frame 155 may be fixed to the mask frame 151 by being inserted into other grooves (not shown) formed in the mask frame 151.

Before or after fixing the deformation prevention frame 155 to the mask frame 151, the mask sheet 152 may be arranged on the mask frame 151 and fixed to the mask frame 151 by being pulled.

The deformation of the mask assembly 150 is reduced after being manufactured, a deposition area that is formed by the mask assembly 150 may be the same as or similar to a designed deposition area.

The magnetic force portion 160 may be arranged inside the chamber 110 to face the display substrate D. The magnetic force portion 160 applies a magnetic force to the mask sheet 152 to apply a force to the mask assembly 150 towards the display substrate D. In particular, the magnetic force portion 160 may prevent the mask sheet 152 from sagging down due to gravity, and moreover may allow the mask sheet 152 to be adjacent to the display substrate D. In addition, the magnetic force portion 160 may maintain a uniform interval between the mask sheet 152 and the display substrate D in the lengthwise direction of the mask sheet 152.

The vision portion 170 may be provided in the chamber 110 to capture an image that indicates positions of the display substrate D and the mask assembly 150. In this case, the vision portion 170 may include a camera for photographing the display substrate D and the mask assembly 150. The positions of the display substrate D and the mask assembly 150 and alignment therebetween may be checked based on the image captured by the vision portion 170, and the second supporter 130 may finely adjust the position of the mask assembly 150 with respect to the display substrate D based on the captured image.

The pressure adjuster 180 may be connected to the chamber 110 to adjust a pressure inside the chamber 110. For example, the pressure adjuster 180 may adjust the pressure inside the chamber 110 to be identical with or similar to the atmospheric pressure. In another example, the pressure adjuster 180 may adjust the pressure in the chamber 110 to be identical with or similar to a vacuum state.

The pressure adjuster 180 may include a connecting pipe 181 connected to the chamber 110 and a pump 182 that is provided on the connecting pipe 181. In this case, external air or gas may be introduced into the chamber 110 through the connecting pipe 181, or air or gas inside the chamber 110 may be purged to the outside of the chamber 110 through the connecting pipe 181 according to operations of the pump 182.

In addition, the apparatus 100 may be used to manufacture another display apparatus (not shown) that will be described later. In particular, when the pressure adjuster 180 adjusts an internal pressure of the chamber 110 to be equal or similar to the atmospheric pressure, the gate valve 110-1 may operate to open the opening part of the chamber 110.

After that, the display substrate D may be carried into the chamber 110 from the outside of the chamber 110. In this case, the display substrate D may be carried into the chamber 110 in various ways. For example, the display substrate D may be carried into the chamber 110 from the outer portion of the chamber 110 via a robot arm, etc. that is arranged outside of the chamber 110. In another embodiment, when the first supporter 120 is of a shuttle type, the display substrate D is mounted on the first supporter 120 by a different robot arm, etc. that is arranged outside of the chamber 110. After the first supporter 120 is withdrawn from the inside of the chamber 110 to the outside of the chamber 110, the first supporter 120 may be carried into the chamber 110. Hereinafter, for convenience of description, an example in which the display substrate D is carried into the chamber 110 from the outside of the chamber 110 via the robot arm arranged outside of the chamber 110 will be described in detail below.

The mask assembly 150 may be arranged inside the chamber 110 as described above. In another embodiment, the mask assembly 150 may be carried into the chamber 110 from the outside of the chamber 110 in a manner that is identically or similarly to the display substrate D. However, for convenience of description, an example in which the mask assembly 150 is arranged inside the chamber 110, and the display substrate D is only carried into the chamber 110 from the outside will be described in detail.

When the display substrate D is carried into the chamber 110, the display substrate D may be mounted on the first supporter 120. The vision portion 170 may capture an image that indicates positions of the display substrate D and the mask assembly 150. For example, the vision portion 170 may capture an image of a first align mark of the display substrate D and a second align mark of the mask assembly 150.

The positions of the display substrate D and the mask assembly 150 and alignment therebetween may be checked based on the first align mark and the second align mark that are obtained in the captured image. The apparatus 100 for manufacturing the display apparatus may include an additional controller (not shown) to check the positions of the display substrate D and the mask assembly 150.

After checking the positions of the display substrate D and the mask assembly 150, the second supporter 130 may finely adjust the position of the mask assembly 150 with respect to the display substrate D. The fine adjustment of the position of the mask assembly 150 may be repeated until the mask assembly 150 is placed at a desired position within a specified tolerance.

After that, the source portion 140 starts operating to supply the deposition material towards the mask assembly 150, and the deposition material that has passed through the plurality of openings 152a may be vapor-deposited on the display substrate D. The pump 182 may suck a gas inside the chamber 110 to discharge the gas to the outside, and thus, an internal pressure of the chamber 110 may be maintained at a pressure lower than the outside pressure (e.g., atmospheric pressure), for example, equal to or similar to a vacuum state.

In the above case, the deposition material may be vapor-deposited on the display substrate D after passing through the plurality of openings 152a arranged in the deposition area (not shown) as described above. The deposition area that the mask assembly 150 provides may be equal to or similar to the designed deposition area.

Therefore, the apparatus 100 for manufacturing the display apparatus may vapor-deposit the deposition material on a region in the display substrate D that may be equal to or similar to a designed region. In addition, since the apparatus 100 for manufacturing the display apparatus may vapor-deposit the deposition material in an accurate pattern by reducing the amount of curving or deformation of the mask frame 151, the manufactured display apparatus may be capable of providing accurate images.

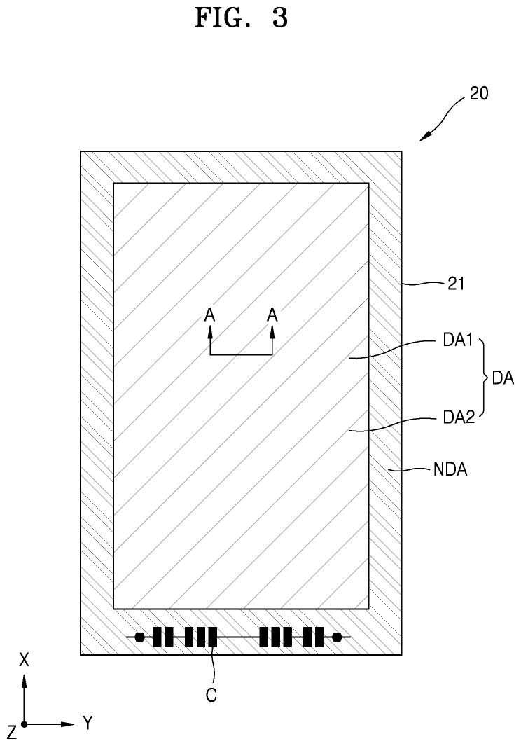

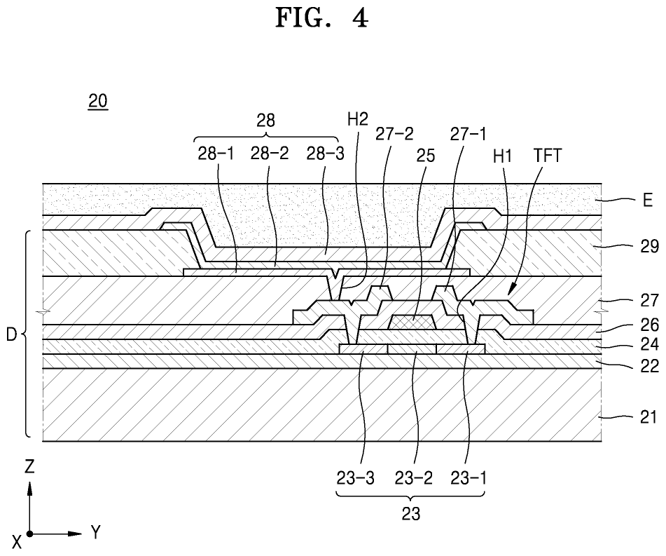

FIG. 3 is a plan view of a display apparatus 20 manufactured by the apparatus for manufacturing the display apparatus of FIG. 1. FIG. 4 is a cross-sectional view taken along line A-A of FIG. 3.

Referring to FIGS. 3 and 4, the display apparatus 20 may include a display area DA and a non-display area NDA that is disposed on an outer portion of the display area DA, wherein the display area DA and the non-display area NDA are defined on a substrate 21. An organic light-emitting device 28 is arranged in the display area DA, and power lines (not shown), etc. may be arranged in the non-display area NDA. In addition, a pad portion C may be arranged in the non-display area NDA.

In the display area DA, a plurality of patterns of various deposition materials that has passed through the deposition area (not shown) described above is formed. The display area DA may be a freeform.

The display apparatus 20 may include the display substrate D, an intermediate layer 28-2 arranged on the display substrate D, and an opposite electrode 28-3 arranged on the intermediate layer 28-2. In addition, the display apparatus 20 may further include a thin film encapsulation layer E arranged on the opposite electrode 28-3.

The display substrate D may include the substrate 21, a thin film transistor TFT, a passivation layer 27, and a pixel electrode 28-1.

The substrate 21 may include a plastic material or a metal material such as stainless steel (SUS) and titanium (Ti). In addition, the substrate 21 may include polyimide (PI). Hereinafter, the substrate 21 including polyimide will be described in detail for convenience of description.

The thin film transistor TFT is arranged on the substrate 21, the passivation layer 27 covers the thin film transistor TFT, and the OLED 28 may be arranged on the passivation layer 27.

A buffer layer 22 including an organic compound and/or an inorganic compound is arranged on an upper surface of the substrate 21, and may include SiOx(x≥1) or SiNx(x≥1).

An active layer 23 is arranged on the buffer layer 22 in a predetermined pattern, and then, the active layer 23 is embedded by a gate insulating layer 24. The active layer 23 includes a source region 23-1, a drain region 23-3, and a channel region 23-2 between the source region 23-1 and the drain region 23-3.

The active layer 23 may include various materials. For example, the active layer 23 may include an inorganic semiconductor material such as amorphous silicon or crystalline silicon. In another example, the active layer 23 may include oxide semiconductor. In yet another example, the active layer 23 may include an organic semiconductor material. Hereinafter, an example in which the active layer 23 includes amorphous silicon will be described below in detail for convenience of description.

The active layer 23 may be obtained by arranging an amorphous silicon layer on the buffer layer 22, crystalizing the amorphous silicon layer to a polycrystalline silicon layer, and patterning the polycrystalline silicon layer. The source region 23-1 and the drain region 23-3 of the active layer 23 are doped with impurities according to a type of the TFT, e.g., a driving TFT (not shown) or a switching TFT (not shown).

A gate electrode 25 corresponding to an active layer 23 and an interlayer insulating layer 26 embedding the gate electrode 25 are arranged on an upper surface of the gate insulating layer 24.

In addition, contact holes H1 are formed in the interlayer insulating layer 26 and the gate insulating layer 24, and after that, a source electrode 27-1 and a drain electrode 27-2 are arranged on the interlayer insulating layer 26 to contact the source region 23-1 and the drain region 23-3 via the respective contact hole H1.

The passivation layer 27 is arranged to cover the TFT obtained as described above, and a pixel electrode 28-1 of the organic light-emitting device (OLED) 28 is arranged on the passivation layer 27. The pixel electrode 28-1 contacts the drain electrode 27-2 of the TFT via a via hole H2 that is formed in the passivation layer 27. The passivation layer 27 may have a single-layered structure or two or more layered structure including an inorganic material and/or an organic material. The passivation layer 27 may be a planarization layer having a flat upper surface for planarizing curves of the underlayers or may be a curved layer having curves according to the curves of underlayers. In addition, the passivation layer 27 may include a transparent insulator to achieve a resonant effect.

After arranging the pixel electrode 28-1 over the passivation layer 27, a pixel-defining layer 29 including an organic material and/or an inorganic material covers the pixel electrode 28-1 and the passivation layer 27, and an opening for exposing at least a portion of the pixel electrode 28-1 is generated in the pixel-defining layer 29.

In addition, the intermediate layer 28-2 and the opposite electrode 28-3 are arranged to overlap at least a portion of the pixel electrode 28-1. In another embodiment, the opposite electrode 28-3 may be arranged on an entire surface of the display substrate D. In this case, the opposite electrode 28-3 may be arranged on the intermediate layer 28-2 and the pixel defining layer 29. Hereinafter, for convenience of description, an example in which the opposite electrode 28-3 is arranged on the intermediate layer 28-2 and the pixel defining layer 29 will be described in detail below.

According to one embodiment, the pixel electrode 28-1 serves as an anode electrode, and the opposite electrode 28-3 serves as a cathode electrode, or vice versa.

The pixel electrode 28-1 and the opposite electrode 28-3 are insulated from each other by the intermediate layer 28-2, and voltages of different polarities are applied to the intermediate layer 28-2 to make an organic emission layer emit light.

The intermediate layer 28-2 may include the organic emission layer. In another example, the intermediate layer 28-2 may include the organic emission layer and at least one of a hole injection layer (HIL), a hole transport layer (HTL), an electron transport layer (ETL), and an electron injection layer (EIL). It is noted that the present disclosure is not limited thereto, that is, the intermediate layer 28-2 may include other various functional layers (not shown) in addition to the organic emission layer.

Here, the intermediate layer 28-2 may be arranged by the apparatus for manufacturing the display apparatus described above.

There may be a plurality of intermediate layers 28-2, and the plurality of intermediate layers 28-2 may form the display area DA. The plurality of intermediate layers 28-2 may be arranged as being spaced apart from one another in the display area DA.

In addition, one unit pixel includes a plurality of sub-pixels, and the plurality of sub-pixels may emit light of various colors. For example, the plurality of sub-pixels may include sub-pixels respectively emitting red light, green light, and blue light, or sub-pixels (not denoted by reference numerals) respectively emitting red light, green light, blue light, and white light.

The sub-pixel may include at least one intermediate layer 28-2. When one sub-pixel is formed, the intermediate layer 28-2 may be arranged by the apparatus for manufacturing the display apparatus as described above.

In addition, the thin film encapsulation layer E may include a plurality of inorganic layers, or inorganic layers and organic layers that are stacked on each other.

The organic layer of the thin film encapsulation layer E may include a polymer. The organic layer of the thin film encapsulation layer E may be a single layer or a stacked layer including polyethylene terephthalate, polyimide, polycarbonate, epoxy, polyethylene, and polyacrylate. The organic layer may include polyacrylate, and for example, may include a polymerized monomer composition including diacrylate-based monomer and triacrylate-based monomer. The monomer composition may further include monoacrylate-based monomer. In addition, the monomer composition may further include a photoinitiator such as TPO that is well known in the art, but is not limited thereto.

The inorganic layer of the thin film encapsulation layer E may be a single layer or a stacked layer including a metal oxide or a metal nitride. For example, the inorganic layer may include any one of SiNx, Al₂O₃, SiO₂, and TiO₂.

The top layer of the thin film encapsulation layer E that is exposed to the outside may be formed of an inorganic layer to prevent intrusion of moisture into the OLED 28.

The thin film encapsulation layer E may include at least one sandwich structure in which at least one organic layer is inserted between at least two inorganic layers. In another example, the thin film encapsulation layer E may include at least one sandwich structure in which at least one inorganic layer is inserted between at least two organic layers. In yet another example, the thin film encapsulation layer E may include a first sandwich structure in which at least one organic layer is inserted between at least two inorganic layers and a second sandwich structure in which at least one inorganic layer is inserted between at least two organic layers.

The thin film encapsulation layer E may include a first inorganic layer, a first organic layer, and a second inorganic layer that are sequentially stacked on the top surface of the OLED 28.

In another example, the thin film encapsulation layer E may include a first inorganic layer, a first organic layer, a second inorganic layer, a second organic layer, and a third inorganic layer that are sequentially on the top surface of the OLED 28.

In yet another example, the thin film encapsulation layer E may include a first inorganic layer, a first organic layer, a second inorganic layer, a second organic layer, a third inorganic layer, a third organic layer, and a fourth inorganic layer that are sequentially stacked on the top surface of the OLED 28.

A halogenized metal layer including lithium fluoride (LiF) may be additionally included between the OLED 28 and the first inorganic layer. The halogenized metal layer may prevent the OLED 28 from being damaged when the first inorganic layer is formed in a sputtering process.

The first organic layer may have a smaller surface area than the second inorganic layer, and the second organic layer may be have a smaller surface area than the third inorganic layer in a plan view.

The display apparatus 20 manufactured by the above-described apparatus may have the display area DA that is equal to or similar to the designed display area, so that the display apparatus 20 may provide accurate images.

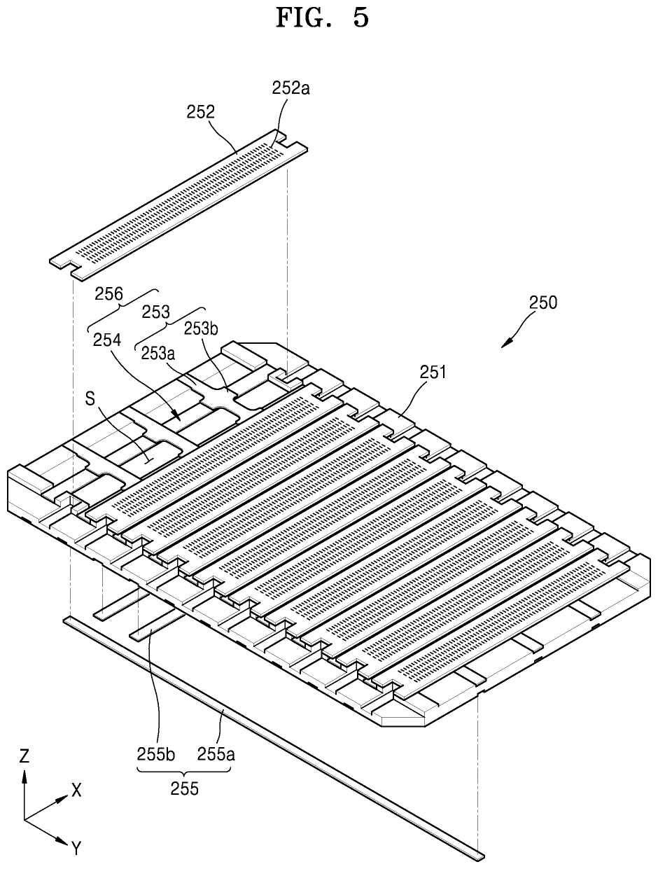

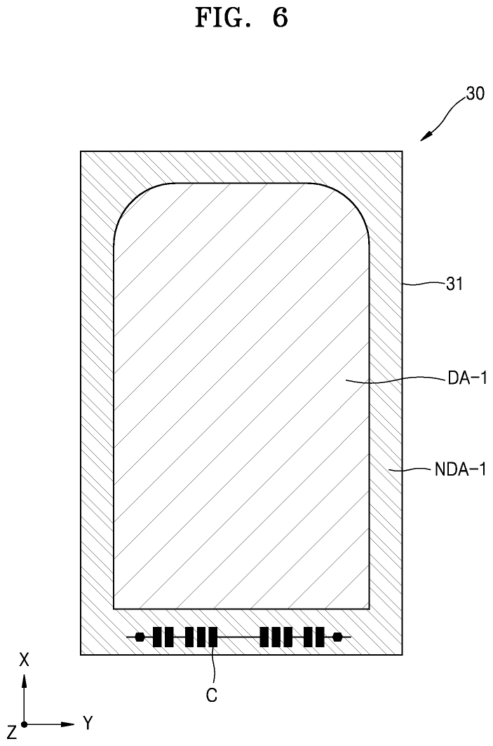

FIG. 5 is an exploded perspective view of a mask assembly 250 according to an embodiment. FIG. 6 is a cross-sectional view of a display apparatus manufactured by using the mask assembly 250 of FIG. 5.

Referring to FIGS. 5 and 6, an apparatus (not shown) for manufacturing a display apparatus may include a chamber (not shown), a first supporter (not shown), a second supporter (not shown), a mask assembly 250, a source portion (not shown), a magnetic force portion (not shown), a vision portion (not shown), and a pressure adjuster (not shown). Here, the chamber, the first supporter, the second supporter, the source portion, the magnetic force portion, the vision portion, and the pressure adjuster are the same as or similar to those of FIGS. 1 and 2, and hereinafter, the mask assembly 250 will be described in detail below.

The mask assembly 250 may include a mask frame 251, a mask sheet 252, one or more support frames 256, and one or more deformation prevention frames 255. Here, the mask frame 251 and the mask sheet 252 are the same as or similar to those of FIGS. 1 and 2, and thus detailed descriptions thereof are omitted.

According to one embodiment, a plurality of support frames 256 may be arranged between the mask frame 251 and the mask sheet 252. The plurality of support frames 256 may be arranged as being spaced from one another on the mask frame 251. As illustrated in FIG. 5, the plurality of support frames 256 may include one or more first support frames 253 and one or more second support frames 254. The first support frames 253 may be arranged across the plurality of mask sheets 252, and each of the plurality of second support frames 254 may be arranged between two adjacent mask sheets 252.

Each of the first support frames 253 may include a first support frame body 253a provided on the mask frame 251, and a first protrusion 253b that protrudes from the first support frame body 253a.

The first support frame body 253a may be provided as a plate of a straight shape. The first support frame body 253a may be arranged in a direction (or first direction, Y-axis direction of FIG. 5) perpendicular to the lengthwise direction of the mask sheet 252.

The first protrusion 253b may protrude from the first support frame body 253a in the lengthwise direction of the mask sheet 252. The first protrusion 253b and the first support frame body 253a may define a boundary of a deposition area S. The first protrusion 253b and the first support frame body 253a may define the boundary of the deposition area S in various shapes. In particular, the first protrusion 253b may define, in the boundary of the deposition area S, an inclined portion that makes a predetermined angle with respect to the first support frame body 253a, a portion provided with a curvature, etc. In this case, the first protrusion 253b may shield some of a plurality of openings 252a in the mask sheet 252. For example, the first protrusion 253b may shield some of the openings 252a arranged at the boundary (or edge) of the deposition area S. In this case, the deposition material may pass through only some of the openings 252a.

Each of the support frames 256 may include a plurality of first protrusions 253b that is arranged to be spaced apart from one another in a lengthwise direction of the first support frame body 253a. In this case, the plurality of first protrusions 253b may be spaced apart from one another along the first support frame body 253a.

The second support frames 254 may be arranged at a predetermined angle with respect to the first support frames 253. The second support frames 254 may be provided as a plate. In this case, the mask frame 251 may include grooves so that the first support frames 253 may not interfere with the second support frames 254, and the first support frames 253 and the second support frames 254 may be arranged at different heights from each other and intersect with each other in a plan view.

The deformation prevention frames 255 may include one or more first deformation prevention frames 255a and one or more second deformation prevention frames 255b respectively corresponding to the first support frames 253 and the second support frames 254. In this case, a width of the first deformation prevention frames 255a may be less than that of the first support frame body 253a, and a width of the second deformation prevention frames 255b may be less than that of the second support frame 254. As such, the deposition material that is vapor-deposited on the display substrate D may not be blocked by the first deformation prevention frames 255a and the second deformation prevention frames 255b at the boundary of the deposition area S.

The plurality of support frames 256 may define at least one deposition area S. A deposition area S may be defined as a region in which the deposition material passes through the plurality of openings 252a arranged on a space defined by two adjacent first support frames 253 and two adjacent second support frames 254. The deposition area S may have a freeform shape, rather than a rectangle or a square. For example, the deposition area S may have a corner that is inclined, a corner of a polygon, or a part of a circle.

The method of manufacturing the mask assembly 250 described above may be the same as or similar to that illustrated with reference to FIGS. 1 and 2.

After the first support frames 253 and the second support frames 254 are fixed to a surface of the mask frame 251 in a state of being pulled. After at least one of the first support frames 253, the second support frames 254, and the mask sheets 252 is fixed to the mask frame 251, at least one of the first deformation prevention frames 255a and the second deformation prevention frames 255b may be fixed to another surface of the mask frame 251 in a state of being pulled as well. As a result, twisting or deformation of the mask frame 251 due to the tensile force applied to the first support frames 253, the second support frames 254, and the mask sheets 252 may be offset by the counter-acting tensile force applied to at least one of the first deformation prevention frames 255a and the second deformation preventions frame 255b to the mask frame 251.

Therefore, the mask assembly 250 may form a deposition area S that is the same as or similar to a designed deposition area S, by reducing twisting or deformation of the mask assembly 250 after being manufactured.

In addition, when a display apparatus 30 is manufactured by the above-described apparatus for manufacturing the display apparatus, the mask assembly 250 may be used.

First, the mask assembly 250 and a display substrate (not shown) are arranged inside the chamber, and then may be aligned by using the vision portion.

After that, the source portion supplies the deposition material to the mask assembly 250, and the deposition material that has passed through the deposition area S of the mask assembly 250 may be vapor-deposited on the display substrate in a predetermined pattern.

Since the mask assembly 250 may not be deformed owing to the first deformation prevention frames 255a and the second deformation prevention frames 255b, the deposition material passing through the openings of the mask sheet 252 may be precisely vapor-deposited on a desired position on the display substrate.

Therefore, the apparatus for manufacturing the display apparatus 30 can form various layers of the display apparatus, for example, an intermediate layer (not shown), in a precise pattern by using the mask assembly 250, the deformation of which is reduced as described above.

Referring to FIG. 6, in the display apparatus 30 manufactured by the above described apparatus for manufacturing the display apparatus, a display area DA-1 of a freeform shape may be arranged on a substrate 31. The display area DA-1 may be surrounded by a non-display area NDA-1 as described above. In this case, an organic light-emitting device (not shown) may be arranged in the display area DA-1, and power lines (not shown), etc. may be arranged in the non-display area NDA-1. In addition, a pad portion C may be arranged in the non-display area NDA-1.

In the display area DA-1, a plurality of patterns of various deposition materials that has passed through the deposition area S described above is formed. The display area DA-1 may be a freeform. As illustrated in FIG. 6, opposite sides of an arbitrary center line that passes through a center of the display area DA-1 may be asymmetrical with each other. In comparison, the display area DA illustrated in FIG. 3 may be symmetrical with each other with respect to an arbitrary center line.

Otherwise, the display apparatus 30 may have a structure that is the same as or similar to that illustrated with reference to FIGS. 3 and 4.

From the foregoing, the display apparatus 30 manufactured by the above described apparatus for manufacturing the display apparatus may provide images accurately due to the intermediate layer implemented with a precise pattern.

According to the embodiments, the deformation of the mask assembly may be reduced. In addition, according to the apparatus and method of manufacturing the display apparatus of the embodiments, the deposition material may be accurately vapor-deposited on the display substrate by using the mask assembly with reduced deformation.

According to the apparatus and method of manufacturing the display apparatus of the embodiments, the display apparatus capable of providing accurate images may be manufactured.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A mask assembly comprising:
a mask frame comprising a first surface and a second surface facing each other;
a support frame on the first surface of the mask frame;
a mask sheet on the mask frame comprising at least one opening; and
a deformation prevention frame on the second surface of the mask frame.

2. The mask assembly of claim 1, wherein the support frame and the deformation prevention frame face each other with respect to the mask frame.

3. The mask assembly of claim 1, wherein the support frame and the deformation prevention frame are coupled to the mask frame in a state in which a tensile force is applied to the support frame and the deformation prevention frame.

4. The mask assembly of claim 1, wherein a width of the support frame in a direction perpendicular to a lengthwise direction of the support frame is greater than a width of the deformation prevention frame in a direction perpendicular to a lengthwise direction of the deformation prevention frame.

5. The mask assembly of claim 1, wherein the deformation prevention frame is arranged perpendicular to a lengthwise direction of the mask sheet.

6. The mask assembly of claim 1, comprising a plurality of deformation prevention frames, and
at least two of the plurality of deformation prevention frames are on the mask frame to intersect with each other.

7. The mask assembly of claim 1, wherein the support frame and the deformation prevention frame have different shapes from each other.

8. An apparatus for manufacturing a display apparatus, the apparatus comprising:
a chamber in which a display substrate is;
a mask assembly facing the display substrate in the chamber; and
a source portion facing the mask assembly in the chamber,
wherein the mask assembly comprises:
a mask frame comprising a first surface and a second surface facing each other;
a support frame on the first surface of the mask frame;
a mask sheet on the support frame comprising at least one opening; and
a deformation prevention frame on the second surface of the mask frame.

9. The apparatus of claim 8, wherein the support frame and the deformation prevention frame face each other with respect to the mask frame.

10. The apparatus of claim 8, wherein the support frame and the deformation prevention frame are coupled to the mask frame in a state in which a tensile force is applied to the support frame and the deformation prevention frame.

11. The apparatus of claim 8, wherein a width of the support frame in a direction perpendicular to a lengthwise direction of the support frame is greater than a width of the deformation prevention frame in a direction perpendicular to a lengthwise direction of the deformation prevention frame.

12. The apparatus of claim 8, wherein the deformation prevention frame is arranged perpendicular to a lengthwise direction of the mask sheet.

13. The apparatus of claim 8, wherein the mask assembly comprises a plurality of deformation prevention frames, and
at least two of the plurality of deformation prevention frames are on the mask frame to intersect with each other.

14. The apparatus of claim 8, wherein the support frame and the deformation prevention frame have different shapes from each other.

15. A method of manufacturing a display apparatus, the method comprising:
arranging a display substrate and a mask assembly in a chamber;
aligning the display substrate and the mask assembly with each other; and
supplying a deposition material from a source portion to the mask assembly, and depositing the deposition material on the display substrate through the mask assembly,
wherein the mask assembly comprises:
a mask frame comprising a first surface and a second surface facing each other;
a support frame on the first surface of the mask frame;
a mask sheet on the support frame comprising at least one opening; and
a deformation prevention frame on the second surface of the mask frame.

16. The method of claim 15, wherein the support frame and the deformation prevention frame face each other with respect to the mask frame.

17. The method of claim 15, wherein the support frame and the deformation prevention frame are coupled to the mask frame in a state in which a tensile force is applied to the support frame and the deformation prevention frame.

18. The method of claim 15, wherein a width of the support frame in a direction perpendicular to a lengthwise direction of the support frame is greater than a width of the deformation prevention frame in a direction perpendicular to a lengthwise direction of the deformation prevention frame.

19. The method of claim 15, wherein the deformation prevention frame is arranged perpendicular to a lengthwise direction of the mask sheet.

20. The method of claim 15, wherein the mask assembly comprises a plurality of deformation prevention frames, and
at least two of the plurality of deformation prevention frames are on the mask frame to intersect with each other.
